(19) United States
(12) Patent Application Publication
(10) Pub. No.: US 2018/0226972 A1
(43) Pub. Date: Aug. 9, 2018

(54) Low Power Buffer with Voltage Conversion

(71) Applicant: Ambiq Micro, Inc., Austin, TX (US)

(72) Inventor: Christophe J. Chevallier, Palo Alto, CA (US)

(21) Appl. No.: 15/887,673

(22) Filed: Feb. 2, 2018

Related U.S. Application Data
(60) Provisional application No. 62/454,745, filed on Feb. 4, 2017.

(51) Int. Cl. H03K 19/0185; H03K 19/00; H01L 27/118

(52) U.S. Cl. CPC H03K 19/018521; H03K 19/0027; H01L 27/11898; H03K 19/018592; H03K 19/018585

(57) ABSTRACT

A voltage conversion circuit and method that includes applying a positive bias to a PMOS gate to source voltage and/or a negative bias to an NMOS gate to source voltage. These biases serve to further reduce the leakage current of the unselected device of a driver while in standby mode, as well as convert an input signal at one voltage potential to an output voltage at a different voltage potential.

### CROSS-REFERENCE TO RELATED APPLICATIONS

This application is related to U.S. Provisional Patent Application Ser. No. 62/454,745, filed Feb. 4, 2017, entitled Low Power Buffer with Voltage Conversion (the “Parent Provisional Application”).

This application claims priority to the Parent Application and hereby claims benefit of the filing dates thereof pursuant to 37 CFR § 1.78(a)(4).

The subject matter of the Parent Application is expressly incorporated herein by reference.

### FIELD OF THE INVENTION

The disclosure generally relates low power down-voltage conversion circuits and methods, and more specifically to semiconductor Complementary Metal-Oxide Semiconductor (“CMOS”) circuits adapted to convert an input signal from a first voltage level to an output signal at a second voltage level with reduced power requirements. The novel low power down-voltage conversion circuits and methods are suitable for use in low power microprocessors, microcontrollers, or power management devices.

### BACKGROUND OF THE INVENTION

In general, in the descriptions that follow, the first occurrence of each special term of art that should be familiar to those skilled in the art of integrated circuits (“ICs”) and systems will be italicized. In addition, when a term that may be new or that may be used in a context that may be new, that term will be set forth in bold and at least one appropriate definition for that term will be provided. In addition, throughout this description, the terms assert and negate may be used when referring to the rendering of a signal, signal flag, status bit, or similar apparatus into its logically true or logically false state, respectively, and the term toggle to indicate the logical inversion of a signal from one logical state to the other. Alternatively, the mutually exclusive Boolean states may be referred to as logic_0 and logic_1. Of course, as is well known, consistent system operation can be obtained by reversing the logic sense of all such signals, such that signals described herein as logically true become logically false and vice versa. Furthermore, it is of no relevance in such systems which specific voltage levels are selected to represent each of the logic states.

Hereinafter, reference to a facility shall mean a circuit or an associated set of circuits adapted to perform a particular function regardless of the physical layout of an embodiment thereof. Thus, the electronic elements comprising a given facility may be instantiated in the form of a hard macro adapted to be placed as a physically contiguous module, or in the form of a soft macro the elements of which may be distributed in any appropriate way that meets speed path requirements. In general, electronic systems comprise many different types of facilities, each adapted to perform specific functions in accordance with the intended capabilities of each system. Depending on the intended system application, the several facilities comprising the hardware platform may be integrated onto a single IC, or distributed across multiple ICs. Depending on cost and other known considerations, the electronic components, including the facility-instantiating IC(s), may be embodied in one or more single- or multi-chip packages. However, unless expressly stated to the contrary, the form of instantiation of any facility shall be considered as being purely a matter of design choice.

In the following detailed description, reference is made to the accompanying drawings which form a part hereof, and in which is shown by way of illustration specific embodiments which may be practiced. These embodiments are described in sufficient detail to enable those skilled in the art to practice the embodiments and disclosure. It is to be understood that other embodiments may be utilized, and that logical, mechanical, electrical, and other changes may be made without departing from the scope of the embodiments and disclosure. In view of the foregoing, the following detailed description is not to be taken as limiting the scope of the embodiments or disclosure.

The terminology used herein is for the purpose of describing particular embodiments only and is not intended to be limiting. As used herein, the singular forms “a”, “an”, and “the” are intended to include the plural forms as well, unless the context clearly indicates otherwise. It will be further understood that the terms “comprises” and/or “comprising” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

It will be appreciated that for simplicity and clarity of illustration, where considered appropriate, reference numerals may be repeated among the figures to indicate corresponding or analogous elements. In addition, numerous specific details are set forth in order to provide a thorough understanding of the implementations described herein. However, it will be understood by those of ordinary skill in the art that the implementations described herein may be practiced without these specific details. In other instances, well-known methods, procedures and components have not been described in detail so as not to obscure the implementations described herein. Also, the description is not to be considered as limiting the scope of the implementations described herein.

The detailed description set forth herein in connection with the appended drawings is intended as a description of exemplary embodiments in which the presently disclosed apparatus and system can be practiced. The term “exemplary” used throughout this description means “serving as an example, instance, or illustration,” and should not necessarily be construed as preferred or advantageous over other embodiments.

Shown in FIG. 1 is a typical general purpose computer system 100. Although not all of the electronic components illustrated in FIG. 1 may be operable in the sub-threshold or near-threshold domains in any particular embodiment, some, at least, may be advantageously adapted to do so, with concomitant reductions in system power dissipation. In particular, in recently-developed battery-powered mobile systems, such as smart-phones, tablets and the like, many of the discrete components typical of desktop or laptop devices illustrated in FIG. 1 are integrated into a single integrated circuit chip. Shown by way of example in FIG. 2 is a typical single-chip microcontroller unit (“MCU”) 200 comprising: a central processing unit (“CPU”) and at least one static random-access memory (“SRAM”) facility 210,220.

As is known, conventional electronic circuits are powered by a voltage applied between two nodes, i.e., the power supply node and the ground node. Furthermore, in many instances, multiple power supplies may be used within a given integrated circuit or electronic facility, each power supply having a voltage different from the others. By way of example, a supply voltage may be provided by a power source such as a battery, e.g., lithium-ion or coin-cell battery. The battery determines the power supply voltage level. This power supply voltage level may be too high or too low for optimal circuit operation, and therefore may require certain adjustments to the voltage supply level. Alternatively, some semiconductor devices such as flash memory cells may require as much as 10 volts (10V) to twenty volts (20V) during a programming operation of the flash memory cells, while the memory read operations of the same may be conducted at a much lower voltage level, i.e., 1.8 volts (1.8V).

SRAM circuits capable of storing digital information are widely used in a variety of mobile and handheld devices, e.g., smart-phones, tablets, laptops, and other consumer electronics products. SRAM facilities may include, without limitation, stand-alone memory circuits, with a dedicated substrate, or embedded memory circuits, where the SRAM circuit shares a substrate with other electronic components.

As is known, MOS transistors have a gate, a source, a drain and a bulk node. As one of ordinary skill in this art would understand, by applying a voltage on the gate the amount of current that can flow from the drain to the source can be modulated. One of the main characteristics of MOS transistors is its threshold voltage. This voltage quantity, in its simplest definition, is the voltage applied on its gate in order to pass current.

In recent years, due to the growth of portable electronics, there has been a push to lower the supply voltage of the circuits used in portable electronic appliances. With a lower supply voltage, and the concomitant reduction in power, smaller batteries may be used. One industry standard technique used in semiconductor devices and their integrated circuits to reduce power is to selectively lower the supply voltage on selected portions of the integrated circuit during a retention mode or standby mode.

### BRIEF SUMMARY OF THE INVENTION

In one embodiment, an integrated circuit facility operating in a standby mode having reduced leakage current, said circuit comprising a first circuit comprising a high threshold voltage PMOS device, and a high threshold voltage NMOS device, the first circuit being adapted to operate in response to a first input a first supply voltage, and a first ground voltage, and develop a first output, a second circuit comprising a second PMOS device comprising a source coupled to a second supply voltage, a gate coupled to said first output, and a drain coupled to a second output, and a second NMOS device comprising a source coupled to a second ground voltage, a gate coupled to said first output, and a drain coupled to said second output, wherein if said first output turns on said second NMOS device, said second PMOS device gate-to-source voltage is positively biased, and if said first output turns on said second PMOS device, said second NMOS device gate-to-source voltage is negatively biased.

In another embodiment, an integrated circuit facility operating in a standby mode having reduced leakage current, said circuit comprising a first circuit comprising a high threshold voltage PMOS device, and a high threshold voltage NMOS device, said first circuit being adapted to operate in response to a first input, and a first supply voltage, and develop a first output, and a second circuit comprising a second PMOS device comprising a source coupled to a second supply voltage, a gate coupled to said first output, and a drain coupled to a second output, a second NMOS device comprising a source coupled to a ground supply, a gate coupled to said first output, and a drain coupled to said second output, wherein if said first output turns on said second NMOS device, said second PMOS device gate-to-source voltage is positively biased.

### BRIEF DESCRIPTION OF THE SEVERAL VIEWS OF THE DRAWINGS

The several embodiments may be more fully understood by a description of certain preferred embodiments in conjunction with the attached drawings in which:

FIG. 1 illustrates, in block diagram form, a general-purpose computer system adapted to instantiate any of the several embodiments;

FIG. 2 illustrates, in block diagram form, a typical integrated system adapted to practice any of the several embodiments;

FIG. 3 illustrates, in block diagram form, a typical voltage conversion facility;

FIG. 4 illustrate, in block diagram form, another typical voltage conversion facility;

FIG. 5 illustrates, in block diagram form, a voltage conversion facility accordingly to some embodiments;

FIG. 6 illustrates, in block diagram form, a voltage conversion facility 600 accordingly to a different embodiment;

FIG. 7 illustrates, in schematic form, an exemplary voltage conversion circuit 700 according to some embodiments;

FIG. 8 illustrates, in schematic form, another exemplary voltage conversion circuit 800 according to some embodiments;

FIG. 9 illustrates, in block diagram form, an exemplary decoder 900 adapted to use the embodiments disclosed herein;

FIG. 10 illustrates, in block diagram form, an exemplary SRAM 1000 adapted to use the embodiments disclosed herein;

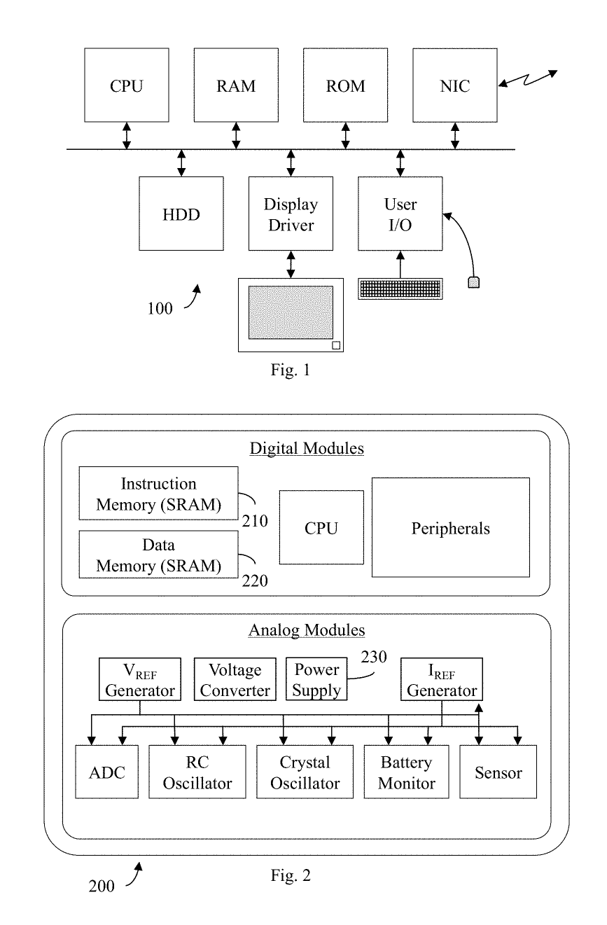

In the drawings, similar elements will be similarly numbered whenever possible. However, this practice is simply for convenience of reference and to avoid unnecessary proliferation of numbers, and is not intended to imply or suggest that identity is required in either function or structure in the several embodiments.

### DETAILED DESCRIPTION

Semiconductor devices may utilize multiple power domains, each power domain with a specified supply voltage level. For power sensitive systems, e.g., battery-powered mobile systems, use of a lower voltage power domain has the advantage of lowering power consumption, as there is less energy spent charging and discharging the nodes of the circuitry inside the power domain. As is known, the energy spent charging a node is proportional to the square of the voltage to which this node is charged. Thus, operating an electronic circuit with a lower voltage tends to reduce or minimize power consumption. A semiconductor device with one or more low-voltage power domains may consume less power than if the semiconductor device did not have the low-voltage power domains.

Semiconductor devices that include multiple power domains and thus multiple logic domains that operate at different supply voltages must communicate across power domain or logic domain boundaries. In order to communicate, or pass signals, from a high voltage power domain to a low voltage power domain, the signals must be converted from high voltage signals to low voltage signals, i.e., the high voltage power domain signal must be level shifted to the low voltage power domain voltage levels.

Voltage conversion is also useful in circuits supporting standby power states. By way of example, many electronic integrated circuits (“IC”) have an active state, where switching of at least some circuit nodes occurs, and a standby state or idle state, where the nodes are idle and are not switching states. Power consumption in the active state is largely determined by the switching current of the transistors that comprise the logic gates and circuit blocks, as well as by the charging and discharging of the capacitive circuit nodes. Contrastingly, the power consumption in the standby state is largely determined by the leakage current, or off current, of the transistors that are inactive or turned off. Leakage current, or off current, is proportional to the size of the device, i.e., the larger the device, the higher the off current. Circuits with a voltage down step may be configured to minimize power consumption in standby. By way of example, a circuit block or logic block operating at a first voltage supply may have output buffers, drivers, or inverters. The power consumption may be reduced or minimized by operating the majority of the circuitry at a first voltage supply, and operating the final output circuit, e.g. buffer, driver, or inverter, at a second, lower voltage.

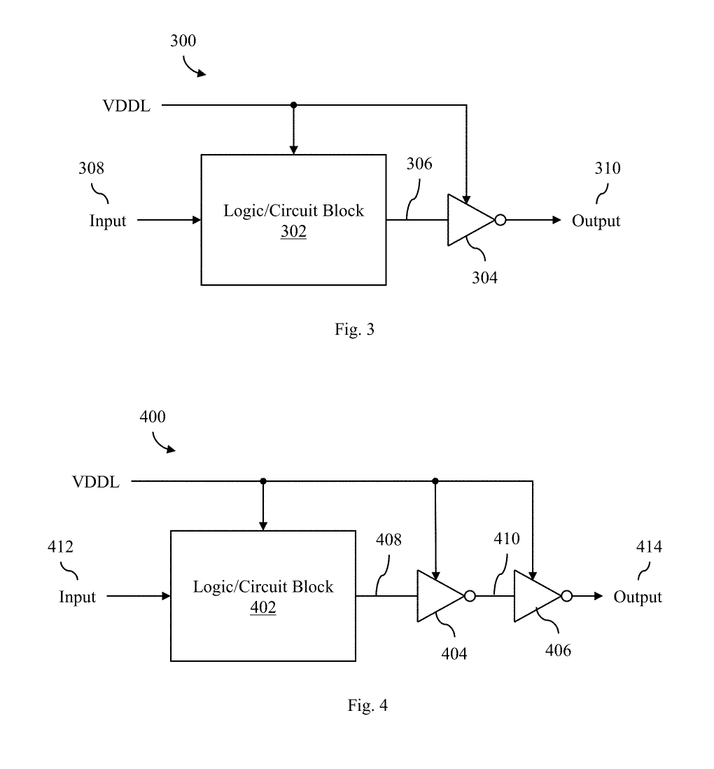

FIG. 3 illustrate, in block diagram form, a typical voltage conversion facility 300. The voltage conversion facility 300 includes a circuit block 302 and an inverting buffer 304. Circuit block 302 receives at least one input signal 308 and develops signal 306. The inverting buffer 304 receives signal 306 and develops and output 310 that is a logically inverted form of signal 306. Both circuit block 302 and inverting buffer 304 are powered by supply voltage VDDL. The input 308 is developed by circuitry of a different voltage power domain that may be at a voltage level that is higher than supply voltage VDDL. During operation, circuit block 302 develops signal 306 as a function of supply voltage VDDL, thus converting the input 308 voltage level to different voltage level that may be lower than input 308. Inverting buffer 304 logically inverts the signal 306, again as a function of supply voltage VDDL. Circuit block 302 may utilize any of the voltage conversion techniques as understood by one of ordinary skill in art of circuit design. In its simplest form, voltage VDDL may be applied directly to the input gates of circuit 302, realizing an inherent voltage down conversion.

FIG. 4 illustrate, in block diagram form, another typical voltage conversion facility 400. The voltage conversion facility 400 includes a circuit block 402, and two inverting buffers 404,406. Circuit block 402 receives an input signal 412 and develops signal 408. The first inverting buffer 404 receives signal or plurality of signals 408 and develops signal 410 that is a logically inverted form of signal 408. The second inverting buffer 406 receives signal 410 and develops signal 414 that is a logically inverted form of signal 410. Circuit block 402, inverting buffer 404, and inverting buffer 406 are powered by supply voltage VDDL. The input 412 is developed by circuitry of a different voltage power domain that may be at a voltage level that is higher than supply voltage VDDL. During operation, circuit block 402 develops signal 408 as a function of supply voltage VDDL, thus converting the input 412 voltage level to different voltage level that may be lower than input 512. Inverting buffer 404 logically inverts the signal 408, again as a function of supply voltage VDDL. Similarly, inverting buffer 406 logically inverts the signal 410 as a function of supply voltage VDDL. Circuit block 402 may utilize any of the voltage conversion techniques as understood by one of ordinary skill in art of circuit design.

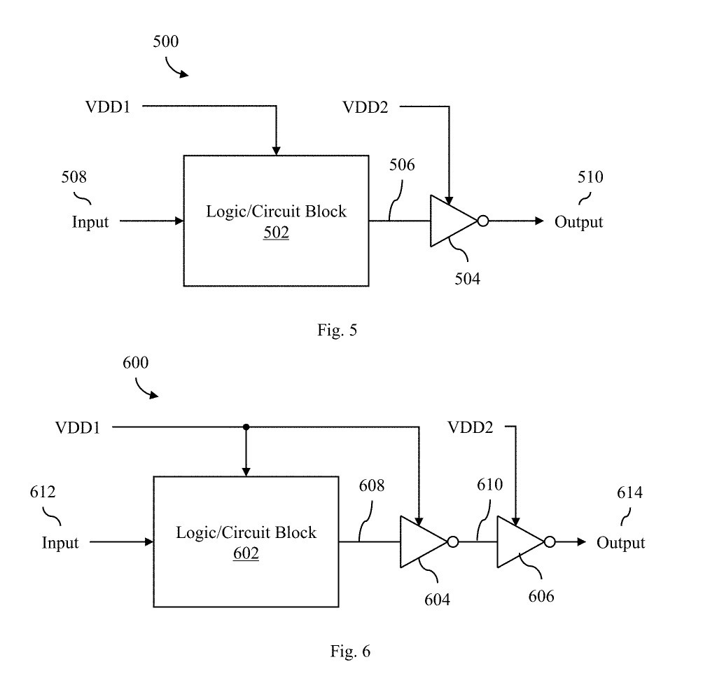

FIG. 5 illustrates, in block diagram form, a voltage conversion facility 500 accordingly to some embodiments. The voltage conversion facility 500 includes a circuit block 502 and an inverting buffer 504. Circuit block 502 receives an input signal or plurality of signals 508 and develops signal 506. The inverting buffer 504 receives signal 506 and develops an output 510 that is a logically inverted form of signal 506. Circuit block 302 is powered by supply voltage VDD1. Inverting buffer 504 is powered by supply voltage VDD2. In this embodiment, supply voltage VDD1 is at a higher potential voltage than supply voltage VDD2. By way of example, VDD1 may be 0.9 volts, and VDD2 may be 0.6 volts. Other supply voltages are anticipated. The input 508 may be developed by circuitry supplied by supply voltage VDD1 such that input 508 is of the same voltage amplitude of circuit block 502. During operation, circuit block 502 develops signal 506 as a function of VDD1, thus converting the input 508 voltage level to the same voltage level as that of input 508. Inverting buffer 504 logically inverts the signal 506, and here, performs a down voltage conversion of signal 506, and develops output signal 510 as a function of VDD2. Output signal 510 may have the same voltage amplitude as supply voltage VDD2.

FIG. 6 illustrates, in block diagram form, a voltage conversion facility 600 accordingly to a different embodiment. The voltage conversion facility 600 includes a circuit block 602, inverting buffer 604, and inverting buffer 606. Circuit block 602 receives an input signal or plurality of signals 612 and develops signal 608. The inverting buffer 604 receives signal 608 and develops signal 610 that is a logically inverted form of signal 608. The inverting buffer 606 receives signal 610 and develops an output 614 that is a logically inverted form of signal 610. Circuit block 502 and inverting buffer 604 are each powered by supply voltage VDD1. Inverting buffer 606 is powered by supply voltage VDD2. In this embodiment, supply voltage VDD1 is at a higher potential voltage than supply voltage VDD2. By way of example, VDD1 may be 0.9 volts, and VDD2 may be 0.6 volts. Other supply voltages are anticipated. The input 612 may be developed by circuitry supplied by supply voltage VDD1 such that input 612 is of the same voltage amplitude of circuit block 602. During operation, circuit block 602 develops signal 608 as a function of VDD1, thus converting the input 612 voltage level to the same voltage level as that of input 608. Inverting buffer 604 logically inverts the signal 608, and again develops signal 610 as a function of VDD1. Thus, signals 608 and signal 610 each have the same voltage amplitude as VDD1. Inverting buffer 606 logically inverts the signal 610, and here, performs a down voltage conversion of signal 610, and develops output signal 614 as a function of VDD2. Output signal 612 may have the same voltage amplitude as supply voltage VDD2.

As is known, CMOS circuitry is built using MOS transistors, NMOS transistors and PMOS transistors. MOS transistors have a gate, a source, a drain and a bulk node. Typically, the current that flows from the drain of a device to the source of a device may be modulated by applying a voltage to the gate of the device. A primary characteristic of a typical MOS device when considering its operation is the threshold voltage of the MOS device, typically abbreviated as Vₜₕ. The threshold voltage is the voltage applied between gate and source of a MOSFET that is needed to turn the device on for linear and saturation regions of operation, and thus to pass current through the device. With a sufficiently high supply voltage, circuitry can be build using high threshold voltage MOS devices. One advantage of a high threshold voltage MOS device is that when its gate is turned off, i.e., V_{gs} is 0 volts, the leakage current from drain to source is very low. Accordingly, the device consumes very little power while in the off state. Generally, however, high threshold voltage MOS device are not efficient when operating in a low supply voltage environment. Signals developed by high threshold voltage MOS devices in a low supply voltage environment are typically of too low a voltage level to allow the high threshold voltage MOS device to pass large amounts of current. This inefficiency in passing large current values negatively effects the switching speeds of the associated MOS devices. As is known, low threshold devices are more effective and efficient in low supply voltage environments, as they are able to pass sufficient current to achieve proper switching speeds. However, low threshold MOS devices typically pass more leakage current when in the off state than their high threshold counterparts.

Placing a MOS device in its respective off state is accomplished by bringing its gate to source voltage (V_{gs}) to zero volts (0V). In the case of a PMOS device, with its source tied to a supply voltage, applying a voltage to the gate of the PMOS device, where the applied voltage is equal to the supply voltage, effectively brings its V_{gs} to 0V, thus placing the PMOS transistor into its off state. In the case of a NMOS devices, with its source tied to ground (GND) or zero volts, applying a voltage to the gate of the NMOS device, where the applied voltage is equal to the GND voltage, effectively brings its V_{gs} to 0V, thus placing the NMOS transistor into its off state. The leakage current for each of the PMOS and NMOS in their off state is commonly known as T_{off}. By applying a negative V_{gs} to an NMOS transistor, or by applying a positive V_{gs} to a PMOS transistor, I_{off} may be significantly reduced. By way of example, a positive V_{gs} applied to a PMOS device may be where the source of the PMOS device is connected to a supply voltage at 0.6 volts, and the gate of the PMOS device is connected to a signal whose voltage is at 0.9 volts. Similarly, by way of example, a negative V_{gs} applied to an NMOS device may be where the source of the NMOS device is connected to a GND voltage at 0.3 volts, and the gate of the NMOS device is connected to a signal whose voltage is at 0 volts. Other voltage combinations are anticipated.

Referring back to FIG. 3 and FIG. 4, all circuit blocks 302, 304, 402, 404, and 406 are supplied by the low supply voltage. Therefore, as is understood, low threshold devices should be used for optimum functionality and switching speeds. The use of low threshold devices in this instance will significantly increase the leakage current through the PMOS and NMOS devices that are in the off state.

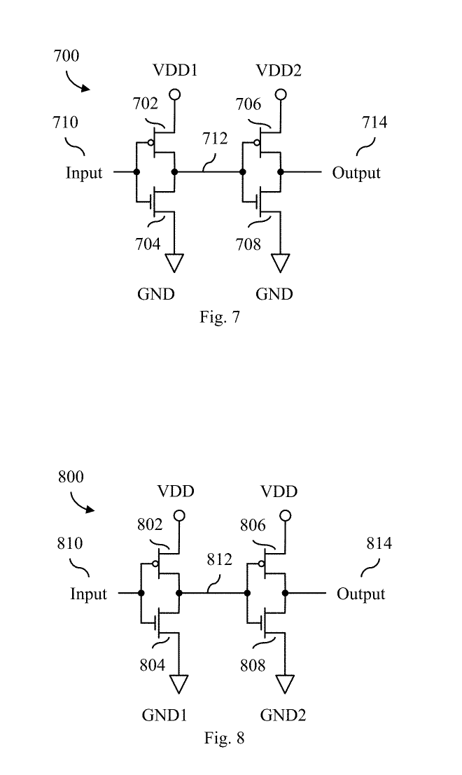

FIG. 7 illustrates, in schematic form, an exemplary voltage conversion circuit 700 according to some embodiments. Voltage conversion circuit 700 includes PMOS 702, NMOS 704, PMOS 706, and NMOS 708. PMOS 702 and NMOS 704 receive as input the signal input 710 and develop the signal 712 as a function of input 710 and the supply voltage VDD1. PMOS 706 and NMOS 708 receive as input the signal 712 and develop the output 714 as a function of signal 712 and the supply voltage VDD2. VDD1 may be at a higher voltage potential than VDD2, i.e., VDD1 may be 0.9V, and VDD2 may be 0.6V. PMOS 702 and NMOS 704 may be high threshold voltage devices. PMOS 706 and NMOS 708 are low threshold voltage devices. During a standby mode, where circuits are held in a state to reduce or minimize switching activity, typically, output 714 will be asserted as a logic_0 or zero volts. As is understood, the implications of asserting a logic-0 on output 714 is that signal 712 will be asserted as a logic_1, or at a voltage potential substantially the same as the supply voltage of the preceding circuit, i.e., in this case VDD1. In this case, NMOS 708 will be selected, turned on, or in the on state, i.e., V_{gs} of NMOS 708 will be approximately 0.9V. Likewise, PMOS 706 will be unselected, turned off, or in the off state. In this instance, however, the PMOS 706 V_{gs} will be positively biased, i.e., the V_{gs} of PMOS 706 will be approximately 0.3V. This positive bias is because input signal 712 is sourced from power domain with a supply voltage of VDD1, or 0.9V, and the PMOS 706 has a source voltage of VDD2, or 0.6V. In this manner, Vgs is positively biased and concomitantly reduces the Ioff, or leakage current, of PMOS 706.

A similar structure can be developed which will negatively bias the NMOS device of output inverter in the case where the output is high in standby mode, and achieve a similar leakage power reduction. FIG. 8 illustrates, in schematic form, another exemplary voltage conversion circuit 800 according to some embodiments. Voltage conversion circuit 800 includes PMOS 802, NMOS 804, PMOS 806, and NMOS 808. PMOS 802 and NMOS 804 receive as input the signal input 810 and develop the signal 812 as a function of input 810 and the ground voltage GND1. PMOS 806 and NMOS 808 receive as input the signal 812 and develop the output 814 as a function of signal 812 and the ground voltage GND2. GND1 may be at a lower voltage potential than GND2, i.e., GND1 may be 0.0V, and GND2 may be 0.3V. PMOS 802 and NMOS 804 may be high threshold voltage devices. PMOS 806 and NMOS 808 may be low threshold voltage devices. During a standby mode, where circuits are held in a state to reduce or minimize switching activity, typically, output 814 may be asserted as a logic_1 or at the supply voltage VDD volts. As is understood, the implications of asserting a logic_1 on output 714 is that signal 712 will be asserted as a logic 0, or at a voltage potential substantially the same as the ground voltage of the preceding circuit, i.e., in this case GND1. In this case, PMOS 806 will be selected, or in the on state, i.e., V_{gs} of PMOS 806 will be approximately 0.9V. Likewise, NMOS 808 will be unselected, or in the off state. In this instance, however, the NMOS 808 V_{gs} will be negatively biased, i.e., the V_{gs} of NMOS 808 will be approximately −0.3V. This positive bias is because input signal 812 is sourced from power domain with a ground voltage of GND1, or 0.0V, and the NMOS 808 has a source voltage of GND2, or 0.3V. In this manner, V_{gs} is positively biased and concomitantly reduces the I_{off}, or leakage current, of NMOS 808.

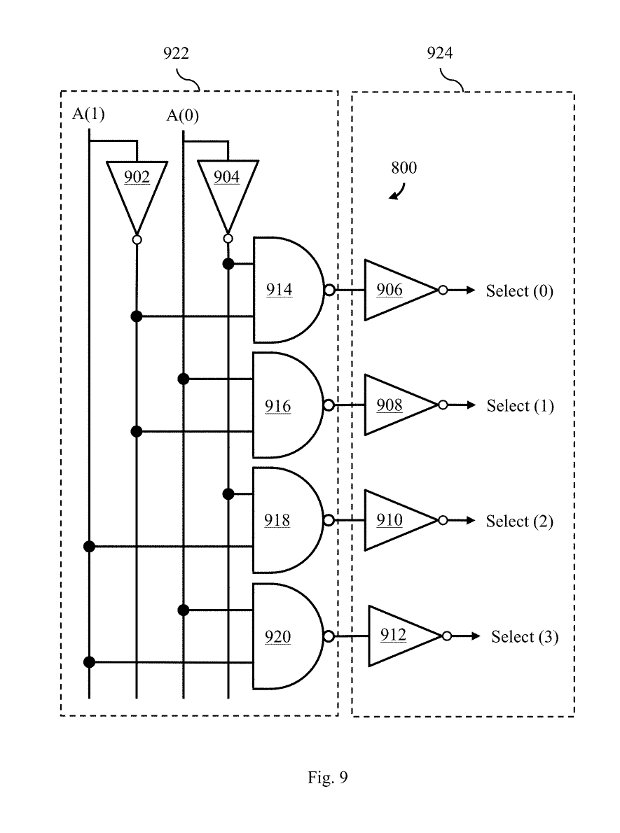

Embodiments such as these may be utilized in various logic blocks to reduce overall leakage current of a semiconductor device. FIG. 9 illustrates, in block diagram form, an exemplary decoder 900 adapted to use the embodiments disclosed herein. Decoder 900 includes two separate power domains with two different supply voltages, i.e., power domain 922, and power domain 924. Power domain 922 includes inverters 902 and 904, and nand gates 914, 916, 918, and 920. Power domain 924 includes inverter 906, 908, 910, and 912. Utilizing the methods of design described in earlier embodiments, logic circuits included in power domain 922 may be supplied by a high voltage supply, i.e., VDD1. Likewise, logic circuits included in power domain 924 may be supplied by low voltage supply, i.e., VDD2. As an example, VDD1 may be 0.9V and VDD2 may be 0.6V. Other voltage level are anticipated.

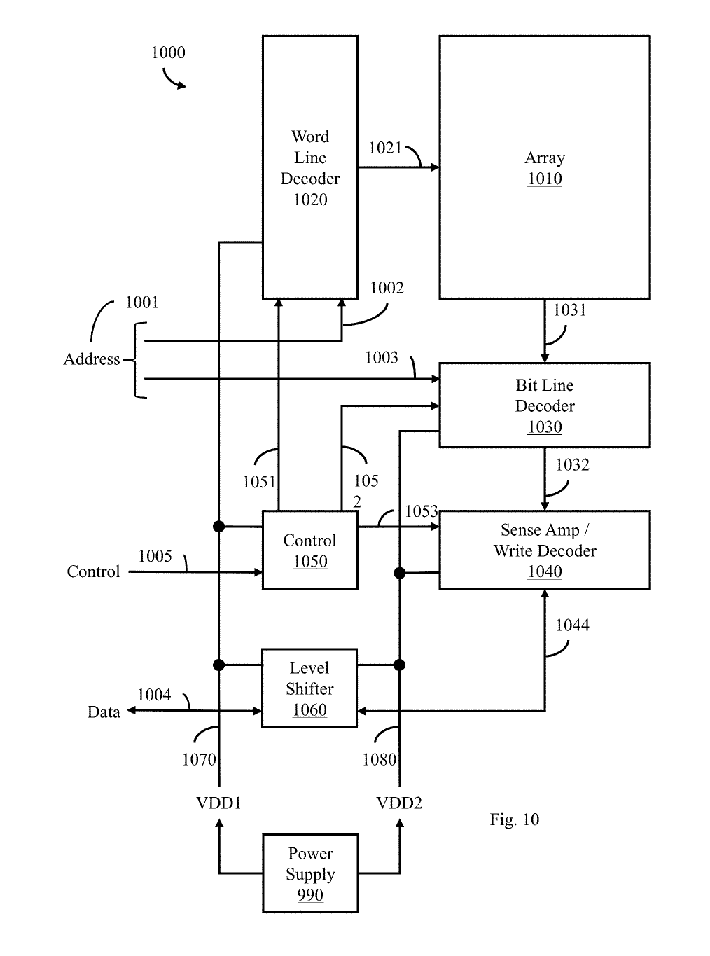

Decoders as described above may be utilized in various circuits and logic blocks to reduce the overall leakage current of a semiconductor device. FIG. 10 illustrates, in block diagram form, an exemplary SRAM 1000 adapted to use the embodiments disclosed herein. SRAM 1000 includes decoders that may employ the previously disclosed embodiments, i.e., bit line decoder 1030 and word line decoder 1020, and further disclosed and illustrated in the pending application “SRAM with Multiple Power Domains”, application Ser. No. 15/345,229, filed 7 Nov. 2016, which is expressly incorporated herein in its entirety. In order to minimize power consumption during idle periods, i.e., to minimize standby current, it is most important to minimize leakage on the large transistors, that is, typically, the transistors driving nodes with a high capacitance, i.e., a data bus, or a set of lines driving bit line decoder 1030, is an example of such a high capacitance nodes. By way of example, high capacitance nodes may be 50 fF or higher.

While these methods and techniques disclosed herein may be used in a variety of circuits within a semiconductor device such as circuit block 302 of FIG. 3 or in the logic gates that comprise the power domain 922 of FIG. 9, it is most efficient to apply the subject matter of this disclosure, i.e. the voltage conversion and biasing techniques, to the circuit driving these high capacitance nodes as disclosed herein. In the former case, power savings accomplished by the application of these voltage conversion and biasing techniques would apply to a part of the subject circuit where widths of the transistors are small, and, concomitantly, the power savings would be small. In the latter case, by shifting the voltage conversion and biasing from the portions of the circuit comprising small or minimum sized transistors, to the output stage, i.e., inverting buffer 606 of FIG. 6 or in the logic gates that comprise the power domain 924 of FIG. 9, which typically drive large capacitive nodes, where the power savings are optimally realized.

A comparison of FIG. 3 to FIG. 5, or of FIG. 4 to FIG. 6 illustrates that power savings is realized because circuit block 502 of FIG. 5 and circuit block 602 of FIG. 6 are designed with high threshold voltage devices and inverting buffer 504 of FIG. 5 and inverting buffer 606 of FIG. 6, each of which drive large capacitive nodes, are designed with low threshold voltage devices with the reverse bias selectively applied to the NMOS or PMOS device of inverting buffer 504 or 606 that is unselected, i.e., not in conduction mode.

Apparatus, methods and systems according to embodiments of the disclosure are described. Although specific embodiments are illustrated and described herein, it will be appreciated by those of ordinary skill in the art that any arrangement which is calculated to achieve the same purposes can be substituted for the specific embodiments shown. This application is intended to cover any adaptations or variations of the embodiments and disclosure. For example, although described in terminology and terms common to the field of art, exemplary embodiments, systems, methods and apparatus described herein, one of ordinary skill in the art will appreciate that implementations can be made for other fields of art, systems, apparatus or methods that provide the required functions. The invention should therefore not be limited by the above described embodiment, method, and examples, but by all embodiments and methods within the scope and spirit of the invention.

In particular, one of ordinary skill in the art will readily appreciate that the names of the methods and apparatus are not intended to limit embodiments or the disclosure. Furthermore, additional methods, steps, and apparatus can be added to the components, functions can be rearranged among the components, and new components to correspond to future enhancements and physical devices used in embodiments can be introduced without departing from the scope of embodiments and the disclosure. One of skill in the art will readily recognize that embodiments are applicable to future systems, future apparatus, future methods, and different materials

All methods described herein can be performed in a suitable order unless otherwise indicated herein or otherwise clearly contradicted by context. The use of any and all examples, or exemplary language (e.g., “such as”), is intended merely to better illustrate the disclosure and does not pose a limitation on the scope of the disclosure unless otherwise claimed. No language in the specification should be construed as indicating any non-claimed element as essential to the practice of the disclosure as used herein.

Terminology used in the present disclosure is intended to include all environments and alternate technologies that provide the same functionality described herein.

Thus it is apparent that a method and apparatus adapted to size circuits more accurately, in particular we could reduce power consumption of SRAM circuits with such techniques while consuming less power than known prior art has been disclosed. Further, we submit that our method and apparatus provides performance generally superior to the best prior art techniques.

What is claimed is:

1. An integrated circuit facility operating in a standby mode having reduced leakage current, said circuit comprising:
a first circuit comprising:
a high threshold voltage PMOS device; and
a high threshold voltage NMOS device;
said first circuit being adapted to:
operate in response to:
a first input;
a first supply voltage; and
a first ground voltage; and
develop a first output;
a second circuit comprising:
a second PMOS device comprising:
a source coupled to a second supply voltage;
a gate coupled to said first output; and
a drain coupled to a second output; and
a second NMOS device comprising:
a source coupled to a second ground voltage;
a gate coupled to said first output; and
a drain coupled to said second output;
wherein if said first output turns on said second NMOS device, said second PMOS device gate-to-source voltage is positively biased; and
if said first output turns on said second PMOS device, said second NMOS device gate-to-source voltage is negatively biased.

2. The integrated circuit facility of claim 1 wherein said first supply voltage is higher than said second supply voltage;

3. The integrated circuit facility of claim 2 wherein said positive bias is further characterized as a difference between said first supply voltage and said second supply voltage.

4. The integrated circuit facility of claim 1 wherein said first ground voltage is lower than said second ground voltage.

5. The integrated circuit facility of claim 4 wherein said negative bias is further characterized as a difference between said first ground voltage and said second ground voltage.

6. The integrated circuit of claim 1 wherein said second PMOS and said second NMOS are further characterized as low threshold voltage devices.

7. The integrated circuit of claim 1 wherein said second output is coupled to a high capacitance load, said load being at least 50 fF.

8. An integrated circuit facility operating in a standby mode having reduced leakage current, said circuit comprising:
a first circuit comprising:
a high threshold voltage PMOS device; and
a high threshold voltage NMOS device;
said first circuit being adapted to:
operate in response to:
a first input; and
a first supply voltage; and
develop a first output; and
a second circuit comprising:
a second PMOS device comprising:
a source coupled to a second supply voltage;
a gate coupled to said first output; and
a drain coupled to a second output;
a second NMOS device comprising:
a source coupled to a ground supply;
a gate coupled to said first output; and
a drain coupled to said second output;
wherein if said first output turns on said second NMOS device, said second PMOS device gate-to-source voltage is positively biased.

9. The integrated circuit facility of claim 8 wherein said first supply voltage is higher than said second supply voltage;

10. The integrated circuit facility of claim 9 wherein said positive bias is further characterized as a difference between said first supply voltage and said second supply voltage.

11. The integrated circuit facility of claim 8 wherein said second PMOS and said second NMOS are further characterized as low threshold voltage devices.

12. The integrated circuit of claim 8 wherein said second output is coupled to a high capacitance load, said load being at least 50 fF.

13. In an integrated circuit facility operating in a standby mode having reduced leakage current, said integrated circuit facility comprising:
a first circuit adapted to operate in response to a first input and a first supply voltage and develop a first output, said first circuit comprising a high threshold voltage PMOS device and a high threshold voltage NMOS device and
a second circuit adapted to operate in response to said first output and a second supply voltage and develop a second output;
said second circuit comprising:
a second PMOS device comprising:
a source coupled to said second supply voltage;
a gate coupled to said first output; and
a drain coupled to said second output;
a second NMOS device comprising:
a source coupled to a ground supply;
a gate coupled to said first output; and
a drain coupled to said second output;
a method for operating said integrated circuit facility, said method comprising:
developing said first output as a function of said first supply;
developing a selected one of:
a positive bias on said second PMOS device gate-to-source voltage if said first output turns on said second NMOS device; and
a negative bias on said second NMOS device gate-to-source voltage if said first output turns on said second PMOS device.

14. The method of claim 13 wherein said first supply voltage is higher than said second supply voltage;

15. The method of claim 14 wherein said positive bias is further characterized as a difference between said first supply voltage and said second supply voltage.

16. The method of claim 13 wherein said second PMOS and said second NMOS are further characterized as low threshold voltage devices.

17. A semiconductor device comprising an integrated circuit facility according to claim 1.

18. A non-transitory computer readable medium including executable instructions which, when executed in a processing system, causes the processing system to perform the steps of a method according to claim 11.
